(19) United States
(12) Patent Application Publication
(10) Pub. No.: US 2008/0165269 A1
(43) Pub. Date: Jul. 10, 2008

(54) METHOD AND APPARATUS FOR OPERATING PORTABLE TERMINAL

(75) Inventors: Soon-Hwa KIM, Suwon-si (KR); Jeong Min You, Yongin-si (KR)

Correspondence Address: THE FARRELL LAW FIRM, P.C., 333 EARLE OVINGTON BOULEVARD, SUITE 701, UNIONDALE, NY, 11553, US

(73) Assignee: Samsung Electronics Co., Ltd., Suwon-si (KR)

(21) Appl. No.: 11/972,358

(22) Filed: Jan. 10, 2008

(30) Foreign Application Priority Data
Jan. 10, 2007 (KR) 2007-0002780

(51) Int. Cl. H04N 5/222; H04N 5/50; G09G 5/08; H05K 7/00

(52) U.S. Cl. 348/333.12; 361/679; 348/731; 345/160; 348/E05.097

(57) ABSTRACT

A method and an apparatus for operating a portable terminal are provided. The apparatus includes a planar first body; a planar second body connected to the planar first body so as to rotate about an eccentric hinge axis extending through a lateral surface of the planar first body in a longitudinal direction of the planar first body; a rotation-sensing unit for sensing rotation of at least one of the planar first and second bodies; and a control unit for controlling the portable terminal according to the rotation. An input function is provided according to the rotation.

### PRIORITY

This application claims priority to an application entitled “METHOD AND APPARATUS FOR OPERATING PORTABLE TERMINAL” filed in the Korean Intellectual Property Office on Jan. 10, 2007 and assigned Serial No. 2007-0002780, the contents of which are incorporated herein by reference.

### BACKGROUND OF THE INVENTION

1. Field of the Invention

The present invention relates generally to a portable terminal and, more particularly, to a method for controlling a portable terminal, which has rotatable bodies, based on the rotation of the bodies.

2. Description of the Related Art

As generally known, remarkable development of information communication and semiconductor technologies are accelerating the widespread use of various types of portable terminals. Particularly, recent portable terminals are not just remaining in their traditional realm, but are evolving to reach the realms of other types of terminals (i.e. mobile convergence). For example, some portable terminals incorporate various multimedia functions, such as watching a television broadcast (e.g. mobile broadcasting such as Digital Multimedia Broadcasting (DMB) or Digital Video Broadcasting (DVB)), playing music (e.g. MP3), and photography, in addition to conventional communication functions, such as voice communication and transmitting/receiving messages.

In line with such diversification of functions, portable terminals provide menus for various functions and corresponding contents (e.g. various channels of DMB). However, when a user of a conventional portable terminal wants to select a menu and corresponding contents, he/she must repeatedly press the direction keys in an inconvenient manner. In addition, when the user uses his/her portable terminal as a camera and tries to determine the angle of an object in a preview mode, he/she must search through many menus for fine adjustment. However, keys of conventional portable terminals are not suited to such operations.

### SUMMARY OF THE INVENTION

The present invention has been made in view of the above problems, and the present invention provides a method for operating a portable terminal adapted to conduct an input function according to a rotation of bodies of the portable terminal.

Also, the present invention provides a method for operating a portable terminal, wherein, when the user selects a specific list or function, which has a wide range of selection between upper and lower limits, an easy and quick movement for that selection is made based on the rotation of the portable terminal.

Furthermore, the present invention provides a method for operating a portable terminal, wherein, when a menu needs fine adjustment, the menu can be intuitively adjusted based on the rotation of the portable terminal.

In accordance with an aspect of the present invention, there is provided an apparatus for operating a portable terminal, the apparatus including a planar first body; a planar second body connected to the first body so as to rotate about an eccentric hinge axis extending through a lateral surface of the first body in a longitudinal direction of the first body; a rotation-sensing unit for sensing a rotation of at least one of the first and second bodies; and a control unit for controlling the portable terminal according to the rotation.

The control unit also controls the portable terminal according to a key input signal together with the rotation.

The rotation-sensing unit senses at least one of a rotation angle and a rotation direction. Preferably, the rotation-sensing unit senses the rotation angle by measuring displacement from an initial location to a later location when at least one of the first and second bodies rotates. The rotation-sensing unit senses the rotation angle and normalizes the rotation angle. The rotation-sensing unit linearly senses the rotation angle.

In accordance with another aspect of the present invention, there is provided a method for operating a portable terminal having a planar first body and a planar second body connected to the first body so as to rotate about an eccentric hinge axis extending through a lateral surface of the first body in a longitudinal direction of the first body, the method including sensing a rotation of least one of the first and second bodies and an optional key input in a predetermined mode; and controlling the portable terminal according to the key input and the rotation.

The sensing includes sensing at least one of a rotation angle and a rotation direction. Preferably, the sensing includes measuring displacement from an initial location to a later location when at least one of the first and second bodies rotates. The sensing includes normalizing the rotation angle into a number in a predetermined range so as to correspond to a predetermined function of the portable terminal. The sensing includes sensing the rotation angle so that the rotation angle linearly corresponds to a predetermined function of the portable terminal.

In accordance with another aspect of the present invention, there is provided a method for operating a portable terminal having a planar first body and a planar second body connected to the first body so as to rotate about an eccentric hinge axis extending through a lateral surface of the first body in a longitudinal direction of the first body, the method including sensing a rotation angle of the first and second bodies and a key input in a mode for watching a digital broadcast; and adjusting a broadcasting channel according to the rotation angle and the key input.

The rotation angle is normalized so as to correspond to a channel number of the digital broadcast.

The adjusting includes increasing the channel according to the rotation angle, when the key input is from an upward direction key. The adjusting includes decreasing the channel according to the rotation angle when the key input is from a downward direction key. The adjusting includes resetting the channel to an initial channel when the key input is from a reset key.

In accordance with another aspect of the present invention, there is provided a method for operating a portable terminal having a planar first body and a planar second body connected to the first body so as to rotate about an eccentric hinge axis extending through a lateral surface of the first body in a longitudinal direction of the first body, the method including sensing a rotation angle and a rotation direction of at least one of the first and second bodies in a preview screen mode of a camera function; and adjusting the preview screen according to the rotation angle and the rotation direction.

The rotation angle is brought into linear proportion to magnification of a lens of the camera function of the portable terminal.

The adjusting includes zooming in the preview screen according to the rotation angle when the rotation direction faces clockwise. The adjusting includes zooming out the preview screen according to the rotation angle when the rotation direction faces counterclockwise.

In accordance with another aspect of the present invention, there is provided a method for operating a portable terminal having a planar first body and a planar second body connected to the first body so as to rotate about an eccentric hinge axis extending through a lateral surface of the first body in a longitudinal direction of the first body, the method including locating a cursor at a menu on a main menu screen so as to highlight the menu; sensing a rotation angle of the first and second bodies and a direction key input when at least one of the first and second bodies rotates; moving the cursor according to the rotation angle and the direction key; and highlighting a menu, the cursor having moved to the menu.

The moving includes, when the direction key is an upward direction key, moving the cursor upwards according to the rotation angle. The moving also includes, when the direction key is a downward direction key, moving the cursor downwards. The moving also includes, when the direction key is a leftward direction key, moving the cursor leftwards according to the rotation angle. The moving also includes, when the direction key is a rightward direction key, moving the cursor rightwards according to the rotation angle.

The method further includes executing the menu when a key input for selecting the highlighted menu is sensed.

### BRIEF DESCRIPTION OF THE DRAWINGS

The above and other aspects, features and advantages of the present invention will be more apparent from the following detailed description in conjunction with the accompanying drawings, in which:

FIG. 1 is a perspective view of the front of a portable terminal according to an embodiment of the present invention;

FIG. 2 is a perspective view of the back of the portable terminal shown in FIG. 1;

FIG. 3 is a perspective view of the portable terminal shown in FIG. 1 with its second body rotated by 180°;

FIG. 4 is a perspective view of the portable terminal shown in FIG. 2 with its second body rotated by 180°;

FIG. 5 is a block diagram of the internal construction of a portable terminal according to an embodiment of the present invention;

FIGS. 6A and 6B illustrate a method for sensing the rotation of a portable terminal according to an embodiment of the present invention;

FIGS. 7A and 7B are graphs showing mappings between a function and a rotational angle obtained by sensing the rotation of a portable terminal according to an embodiment of the present invention;

FIG. 8 shows a method for operating a portable terminal according to an embodiment of the present invention;

FIG. 9 shows a method for operating a portable terminal according to an embodiment of the present invention;

FIG. 10 shows a method for operating a portable terminal according to an embodiment of the present invention; and

FIG. 11 shows an exemplary screen for illustrating a method for operating a portable terminal according to an embodiment of the present invention.

### DETAILED DESCRIPTION OF EXEMPLARY EMBODIMENTS

Hereinafter, exemplary embodiments of the present invention are described in detail with reference to the accompanying drawings. The same reference symbols identify the same or corresponding elements in the drawings. Detailed descriptions of constructions or processes known in the art may be omitted to avoid obscuring the invention in unnecessary detail.

It will be assumed in the following description that, when the first and second bodies are fastened to each other, they are in a “normal condition” and, when they are unfastened from each other, they are in a “rotated condition.”

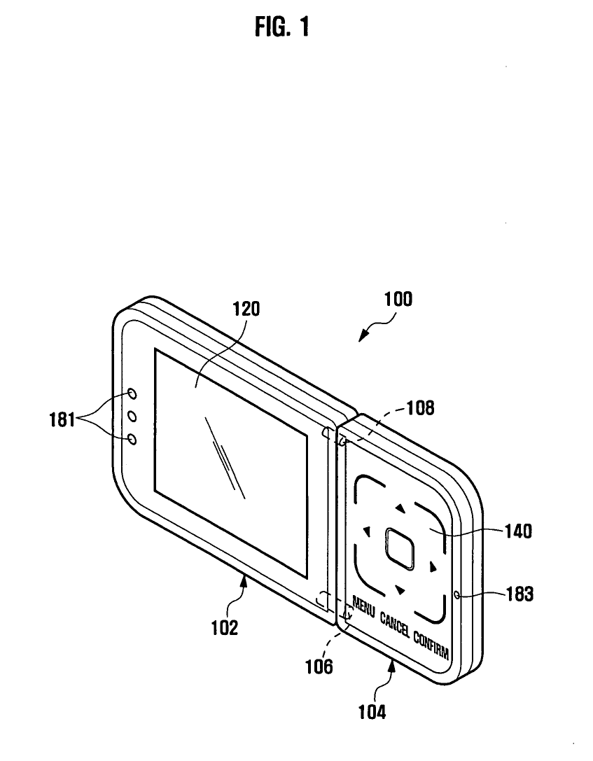

Referring to FIGS. 1 to 4, the portable terminal 100 includes a first body 102, a second body 104, and a hinge module 106 for rotatably connecting the first and second bodies 102 and 104. The first body 102 has a display unit 120 and a speaker 181 on its front surface and a display unit 130 and a speaker 191 on its rear surface. The second body 104 has an input unit 140 and a microphone 183 on its front surface and an input unit 150 and a microphone 193 on its rear surface. The hinge module 106 extends through portions of lateral surfaces of the first and second bodies 102 and 104, which face each other, in the perpendicular direction and connects the first and second bodies 102 and 104 so that they can rotate about a hinge axis A.

The display units 120 and 130 on both surfaces of the first body 102 commonly consist of LCDs (Liquid Crystal Displays). However, other types of display devices, such as AM OLEDs (Active Matrix Organic Light Emitting Diodes) may also be used as the display devices 120 and 130. The first display unit 120 on the front surface has a larger screen size and a higher resolution than the second display unit 130 on the rear surface. For example, the first and second display units 120 and 130 consist of a large QVGA (Quarter Video Graphics Array) LCD and a small QCIF (Quarter Common Intermediate Format) LCD, respectively. However, the types of display units in the present invention are not limited to the presently described exemplary embodiment, and the display units 120 and 130 on both surfaces may have the same size and resolution. It is to be noted that the differentiation between the front and rear surfaces of the portable terminal 100 is purely for convenience of description.

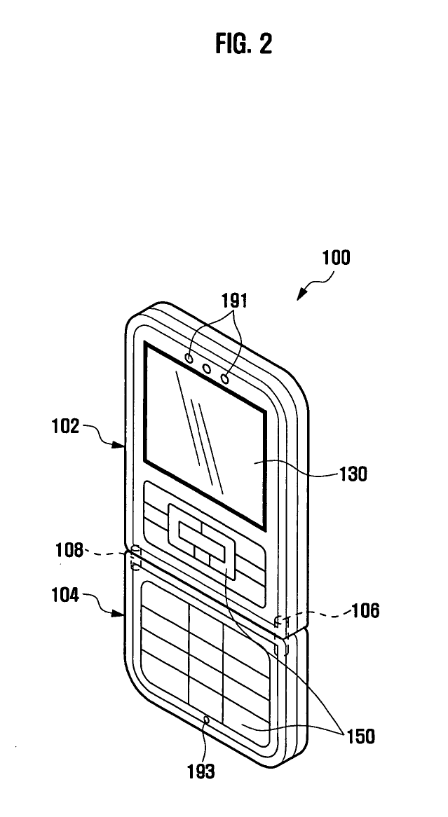

The first display unit 120 may provide a multimedia mode, in which the screen is adapted for a multimedia function, and the second display unit 130 may provide a communication mode, in which the screen is adapted for a conventional function (e.g. communication function). During screen display, the first display unit 120 may provide a horizontal view mode as shown in FIG. 1, and the second display unit 130 may provide a vertical view mode as shown in FIG. 2. However, the types of modes of the display units 120 and 130 are not limited to those of the presently described exemplary embodiment.

The display units 120 and 130 are controlled in such a manner that they are not simultaneously turned off. In other words, when one of the display units 120 and 130 is turned on, the other display unit is turned off.

The speakers 181 and 191 on both surfaces of the first body 102 includes a first speaker 181 positioned on the same surface as the first display unit 120 and a second speaker 191 positioned on the same surface as the second display unit 130. Both speakers 181 and 191 are positioned far from the second body 104.

The input units 140 and 150 on both surfaces of the second body 104 include a first input unit 140 positioned on the front surface and a second input unit 150 positioned on the rear surface, assuming that the portable terminal 100 is in a normal condition. The second body 104 may have an additional third input unit, which consists of a number of input buttons, on its lateral surface. For example, the first and second input units 140 and 150 consist of a touchpad and a keypad, respectively. The touchpad of the first input unit 140 consists of twelve touch buttons, for example, including four-way buttons, menu buttons, a cancellation button, a confirmation button, and a dedicated business provider button. The keypad of the second input unit 150 consists of 3×4 character/numeral keys, four-way search keys, and other types of keys, for example.

The microphones 183 and 193 on both surfaces of the second body 104 include a first microphone 183 positioned on the same surface as the first input unit 140 and a second microphone 193 positioned on the same surface as the second input unit 150. Both microphones 183 and 193 are positioned far from the first body 102.

The hinge module 106 is coupled to the first and second bodies 102 and 104 at their interface. The hinge module 106 has a driving source for rotating the first or second body 102 or 104 in a manual, a semi-automatic, or an automatic mode.

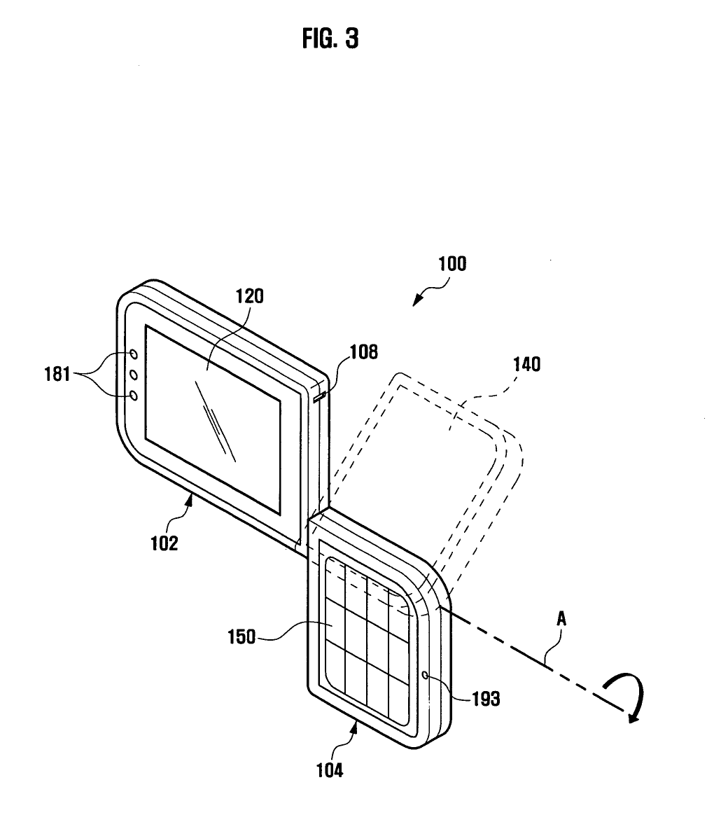

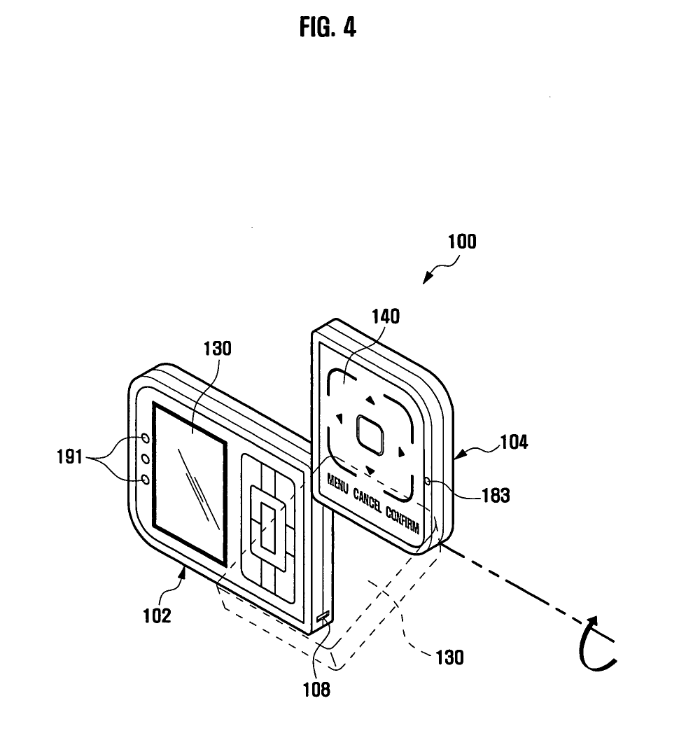

In the manual or the semi-automatic mode, the hinge module 106 is adapted to maintain the second body 104 at an angle relative to the first body 102 after the second body 104 is rotated. For example, the angle may be 0°, 30° to 45°, or 180°. In this case, the angle of 0° corresponds to a normal condition, and other angles correspond to a rotated condition. Particularly, FIGS. 1 and 2 correspond to the normal condition, and FIGS. 3 and 4 correspond to the rotated condition. However, the specific angle at which the rotated condition is maintained is not limited to that in the present invention, and may vary depending on design requirements.

In the automatic mode, if the second body 104 is rotated relative to the first body 102 by the user, the hinge module 106 maintains the rotated condition.

In order to maintain the bodies 102 and 104 in the normal condition more stably, the portable terminal 100 may further include a locking module 108 opposite the hinge module 106. The portable terminal 100 according to the present embodiment can switch from the normal condition shown in FIG. 1 or 2 to the rotated condition shown in FIG. 3 or 4, or vice versa.

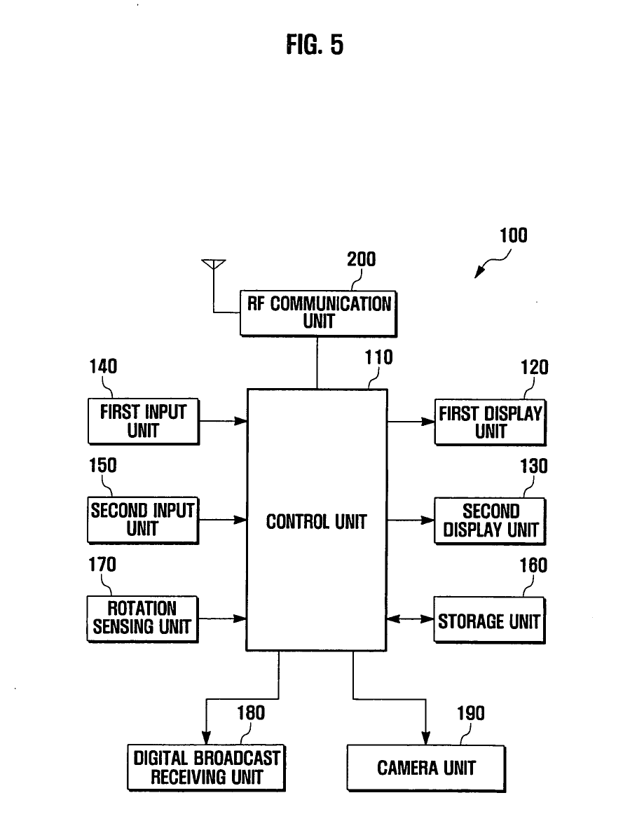

FIG. 5 briefly shows an internal construction of a portable terminal 100, which includes a control unit 110; first and second display units 120 and 130; first and second input units 140 and 150; a storage unit 160; a rotation-sensing unit 170; a digital broadcast receiving unit 180; a camera unit 190; and an RF communication unit 200.

The control unit 110 controls the overall operation of the portable terminal 100, and consists of one or two microprocessor chips. When the control unit 110 consists of two chips, one of them is a dedicated multimedia control chip. Particularly, the control unit 110 controls both speakers and both microphones.

The first and second display units 120 and 130 visually express various pieces of video information regarding the condition and function of the portable terminal 100, respectively. Particularly, one of the first and second display units 120 and 130 is activated and displays video information.

The first and second input units 140 and 150 sense the user's operation, create a corresponding input signal, and transmit the corresponding event signal to the control unit 110.

The storage unit 160 stores a program necessary to control the operation of the portable terminal 110, as well as data occurring when the program is executed.

The rotation-sensing unit 170 senses the rotation of the first and second bodies 102 and 104 and transmits corresponding information to the control unit 110. As used herein, the rotation includes both a rotational angle and a rotation direction, and the rotation-sensing unit 170 senses at least one of the rotation angle and the rotation direction.

When the first and second bodies 102 and 104 of the portable terminal 100 according to an embodiment of the present invention are unfastened from each other and rotated, one of the rotation angle and the rotation direction is sensed so that a corresponding function is executed. The function may be executed together with a key input. To this end, according to an embodiment of the present invention, a sensor is used to sense the fastened/unfastened condition of the first or second body 102 or 104, as well as at least one of the rotation angle and the rotation direction. The rotation-sensing unit 170 may include such a sensor so as to sense the rotation angle, the rotation direction, and the fastened/unfastened condition and transmit corresponding information to the control unit 110.

According to an embodiment of the present invention, the portable terminal 100 is configured in such a manner that at least one of its first and second bodies 102 and 104 can rotate. Considering that the user generally controls the portable terminal 100 with reference to a currently activated display unit, the second body 104 is preferably rotated while the first body 102 is supported. Unless otherwise specified, rotation of at least one of the first and second bodies 102 and 104 will hereinafter be referred to as “rotation of the body (bodies)” or “rotation” as a whole.

The digital broadcast receiving unit 180 may be a digital broadcast receiver adapted for DMB (Digital Multimedia Broadcasting), DVB (Digital Video Broadcasting), or Media Forward-Link-Only (MediaFLO). The digital broadcast receiving unit 180 may incorporate a tuner, a demodulator, and a decoder. Alternatively, the digital broadcast receiving unit 180 may solely consist of a tuner and a demodulator. In the latter case, the control unit 110 is in charge of the decoding.

The camera unit 190 may have a sensor and an image-processing module. Alternatively, the camera unit 190 may solely have a sensor. In the latter case, the control unit 110 is in charge of the image processing.

The RF communication unit 200 may consist of an RF transceiver, a modem, and a codec. Alternatively, the RF communication unit 200 may solely consist of an RF transceiver. In the latter case, the control unit 100 has a modem and a codec.

A method for controlling a portable terminal, which is constructed as mentioned above, and a mapping between a function and rotation of a portable terminal will now be described.

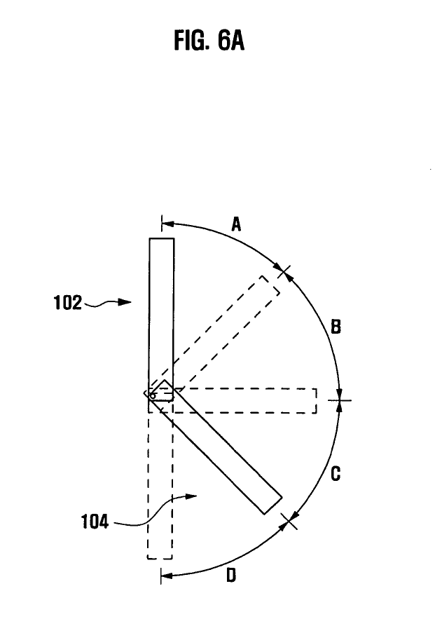

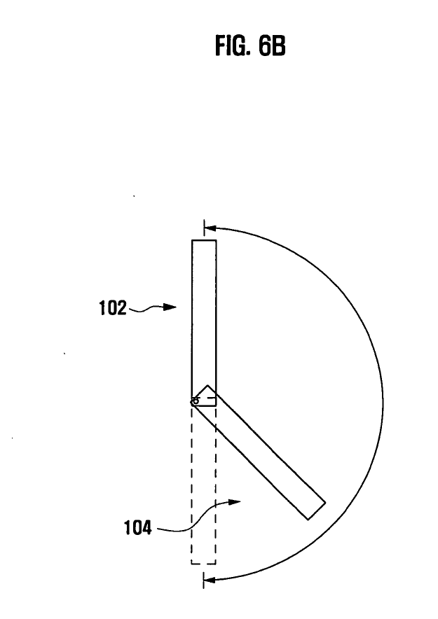

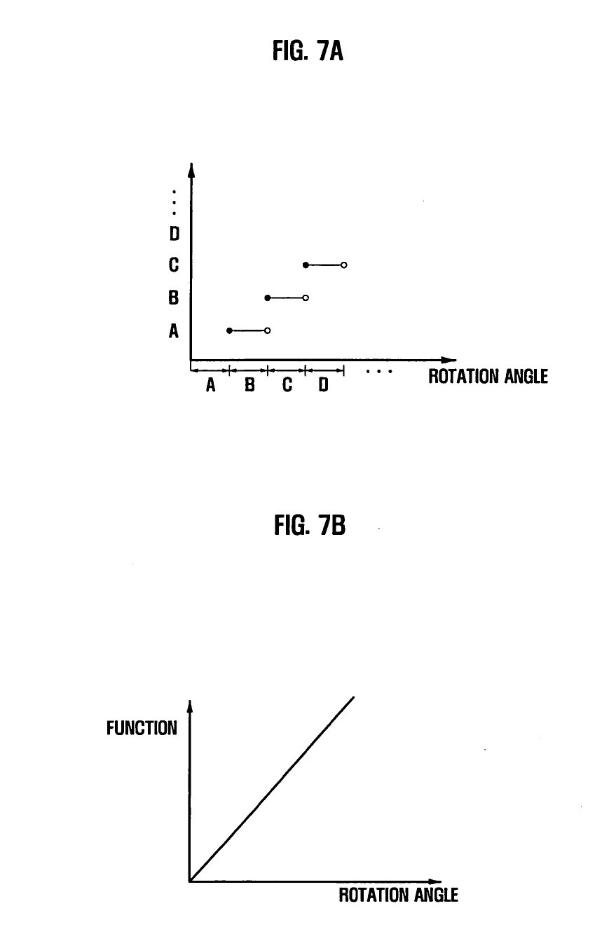

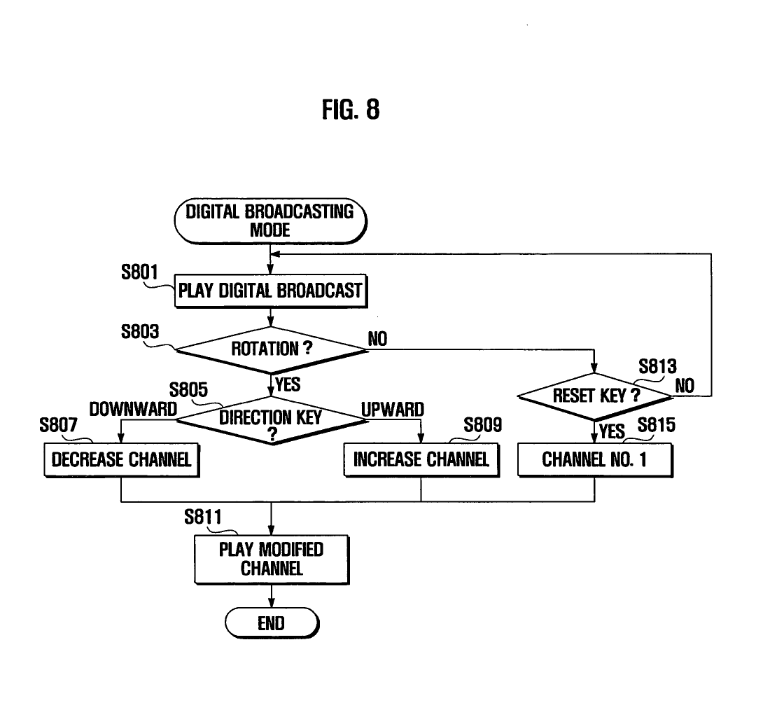

FIGS. 6A and 6B show a method for sensing the rotation of a portable terminal, and FIGS. 7A and 7B are graphs showing mappings between a function and a rotational angle obtained by sensing the rotation of a portable terminal, according to an embodiment of the present invention.

According to an embodiment of the present invention, the portable terminal conducts an input function based on rotation of the second body 104 relative to the first body 102. In other words, the input unit functions based on rotation of the bodies. A number of examples of the input function based on rotation will now be described.

Referring to FIG. 6A, if the second body 104 is rotated relative to the first body 102 by the user, the rotation-sensing unit 170 senses the rotation angle, determines a specific range to which the sensed rotation angle belongs, and transmits resulting information to the control unit 110, which then conducts a corresponding function.

The rotation-sensing unit 170 senses the rotation angle, determines which section (A, B, C, or D) corresponds to the rotated condition, and transmits resulting information to the control unit 110. Such designation of each range of rotation angles as a corresponding section according to an embodiment of the present invention is referred to as normalization. Referring to FIG. 7A, which shows a graph featuring a step function, such a normalized rotation angle maps onto a specific function. For example, rotation angles may map onto a menu having four indices. In this case, a menu can be selected by conducting a four-stage input function based on the range of rotation angles of the portable terminal 100.

Such an input function is useful when there are many indices to choose from. For example, when a digital broadcasting service provides a hundred channels, the user can search through the wide range of channels based on rotation. An example of the input function based on normalized rotation angles will be described later in more detail.

Referring to FIG. 6B, if the second body 104 is rotated relative to the first body 102 by the user, the rotation-sensing unit 170 linearly senses the rotation angle and transmits resulting information to the control unit 110, which then conducts a corresponding function. The rotation-sensing unit 170 may linearly map the rotated condition onto a specific function, as shown in the graph of FIG. 7B. Particularly, the rotation-sensing unit 170 can conduct an input function requiring fine adjustment, such as adjustment of zoom-in/zoom-out magnification of a camera, adjustment of screen brightness, adjustment of sensitivity to light, adjustment of the area of a diaphragm, etc. An example of the input function based on the linearity of rotation angles will be described later in more detail.

Although it has been assumed in the description of two embodiments of the present invention that a rotation angle is sensed after the bodies switch from a fastened condition to a rotated condition, the time of sensing a rotation angle is not limited to that in the present invention. For example, when one of the bodies rotates, the rotation-sensing unit 170 measures the difference in displacement between former and latter positions and determines the rotation angle accordingly.

If necessary, the rotation-sensing unit 170 can sense a rotation angle and a rotation direction at the same time.

A method for adjusting the channel while watching a digital broadcast according to an embodiment of the present invention will now be described.

FIG. 8 shows a method for operating a portable terminal according to an embodiment of the present invention.

According to the present embodiment, when the number of items that needs to be adjusted (e.g. number of channels available from a digital broadcasting service) is specified, the rotation angle is normalized according to the channel number. Such normalization may follow the mapping shown in the graph of FIG. 7A, wherein the channel number increases/decreases in relation to the rotation angle as a step function.

Assuming that a digital broadcasting service provides sixty channels and that 3° is assigned to each channel, the channel number does not increase if a body rotates by 1° or 2°. The channel number increases by one when the body rotates by 3° or more.

Referring to FIG. 8, the portable terminal 100 is playing a digital broadcast, in Step S801. In general, when the user selects a digital broadcast menu, the corresponding digital broadcast is played after a predetermined period of loading time. The same occurs when a shortcut is used. It is assumed that the user is currently watching Channel No. 10.

If the user presses a direction key and rotates a body, the control unit 110 senses the rotation angle by using the rotation-sensing unit 170, in Step S803, and senses the direction of the direction key, in Step S805. The rotation angle may be temporarily stored if necessary. If the user selects the reset key without rotating the body, the control unit 110 senses the selection, in Step S813.

If a downward direction key has been sensed, in Step S805, the control unit 110 decreases the channel number based on the rotation angle, in Step S807, and controls the first display unit 120 so as to play broadcasts via the corresponding channel, in Step S811. If the body has rotated by 10°, broadcasts are played via channel no. 7. If an upward direction key has been sensed, in Step S805, the control unit 110 increases channel number based on the rotation angle, in Step S809, and controls the first display unit 120 so as to play broadcasts via the corresponding channel, in Step S811. If the body has rotated by 20°, broadcasts are played via Channel No. 16.

The user may select the reset key while watching a digital broadcast. The control unit 110 senses the user's selection, in Step S813, switches to Channel No. 1, in Step S815, and broadcasts programs via Channel No. 1. One of the free keys may be designated as the reset key so that, when there are many channels available, the user can easily jump to a lower channel number. As such, the present invention normalizes the rotation angle so as to increase/decrease the channel number accordingly.

Although an embodiment of the present invention has been described with regard to search of channels alone, the present invention is not limited to search of channels alone. For example, the volume of a digital broadcast can be adjusted by rotating a body and sensing the leftward or rightward direction key. Those skilled in the art can easily understand that various modifications are possible without departing from the scope of the present invention.

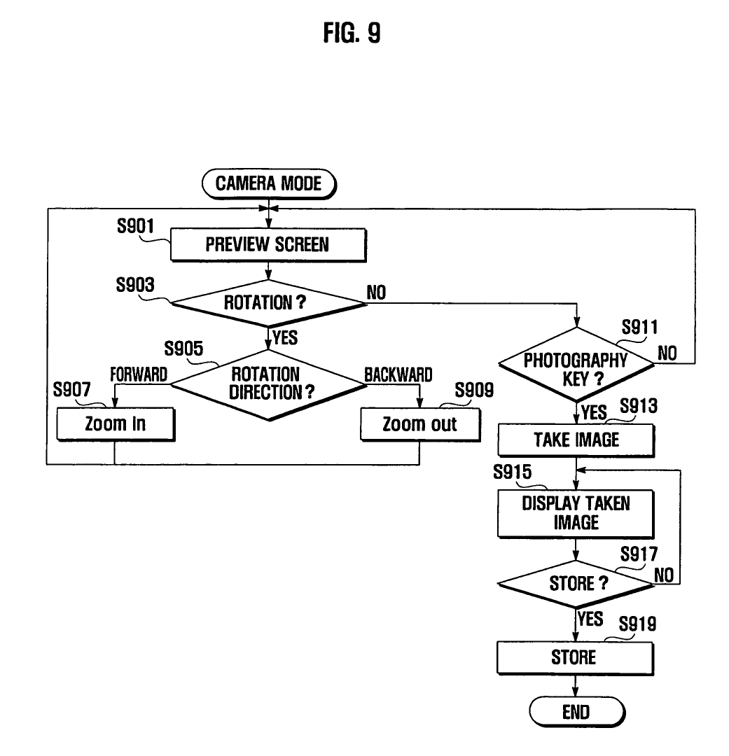

A method for zooming in/out based on rotation of a body of a portable terminal in a camera mode will now be described. FIG. 9 shows a method for operating a portable terminal according to an embodiment of the present invention.

Unlike the channel number as in the above-mentioned embodiment, the zoom-in function of a camera is not to be normalized. Considering that, in the case of a zoom-in, the user wants fine adjustment to his/her taste, the zoom-in is preferably reflected on the screen so that the rotation angle is in linear proportion to the magnification of a lens of the camera as shown in the graph of FIG. 7B. In other words, the zoom-in is linearly executed in relation to the rotation angle.

Referring to FIG. 9, the portable terminal 100 is assumed to be in a camera mode, which can be selected through multiple stages of menus or with a shortcut.

The control unit 110 controls the first display unit 120 so as to provide a preview screen, in Step S901. The user can determine the angle of a desired object with reference to the preview screen. It is customary to use a zoom-in/out function to determine the angle of objects.

If a body is rotated by the user, the controller 110 senses the rotation by using the rotation-sensing unit 170, in Step S903, and determines whether the rotation has occurred clockwise or counterclockwise by using the rotation-sensing unit 170, in Step S905. If it is determined that the rotation has occurred clockwise, in Step S905, the control unit 110 zooms in as much as the rotation angle, in Step S907, and provides a preview screen, in Step S901, in which the zoom-in is reflected. If it is determined that the rotation has occurred counterclockwise, in Step S905, the control unit 110 zooms out as much as the rotation angle, in Step S909, and provides a preview screen, in Step S901, in which the zoom-out is reflected. The user can adjust the angle of the preview screen by rotating a body clockwise/counterclockwise, which corresponds to zoom-in/out, in Steps S903-S909. This enables fine adjustment or intuitive adjustment.

If no rotation has been detected, in Step S903, the control unit 110 monitors if the user selects a photography key from the preview screen, in Step S911. If the user's selection is sensed, the control unit 110 photographs an object with the camera unit 190, in Step S913. Then, the control unit 110 controls the first display unit 120 so as to display the taken image, in Step S915. When the user wanting to store the image selects a storage key, the control unit 110 senses the user's selection, in Step S917 and stores the image, in Step S919.

Although an embodiment of the present invention has been described with regard to zoom-in/out alone, the present invention is not limited to zoom-in/out alone. For example, the present invention is suitable for any application requiring fine adjustment, such as adjustment of screen brightness or diaphragm size.

A method for selecting a menu based on rotation of a body and input of a direction key from a main menu screen will now be described.

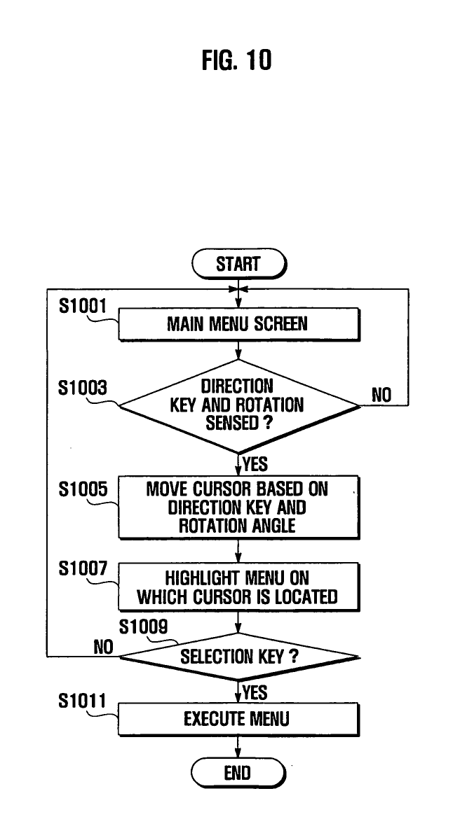

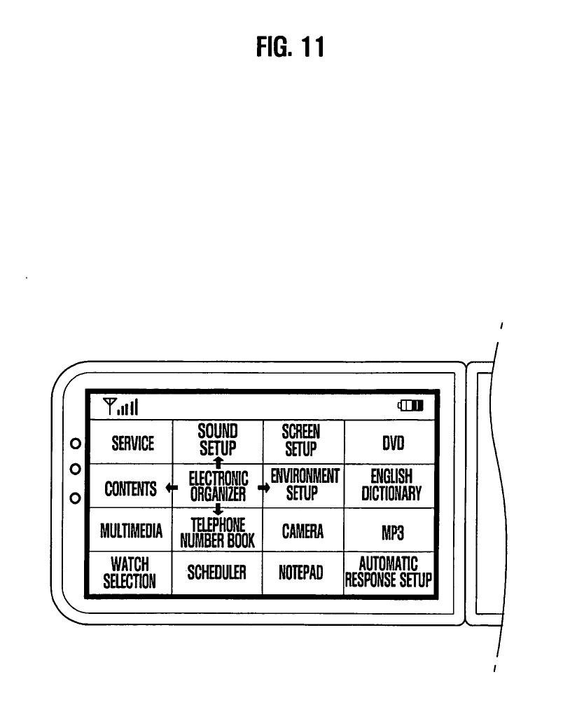

FIG. 10 shows a method for operating a portable terminal according to an embodiment of the present invention; and FIG. 11 shows an exemplary screen for illustrating a method for operating a portable terminal according to an embodiment of the present invention.

Referring to FIG. 10, the control unit 110 provides a main menu screen, which corresponds to the highest depth of menus, in Step S1001. On the main menu screen, as shown in FIG. 11, the cursor is located on a menu selected by the user for the last time, and that menu is highlighted.

If the user selects a direction key and rotates a body, the control unit 110 senses the selection and rotation by using the rotation-sensing unit 170, in Step S1003, and moves the cursor based on the direction key and the rotation angle, in Step S1005. Then, the control unit 110 highlights a menu on which the cursor is located, in Step S1007.

If an upward direction key is sensed, in Step S1003, the control unit 110 moves the cursor upwards as much as the rotation angle, in Step S1005. If a downward direction key is sensed, in Step S1003, the control unit 110 moves the cursor downwards as much as the rotation angle, in Step S1005. If a leftward direction key is sensed, in Step S1003, the control unit 110 moves the cursor leftwards as much as the rotation angle, in Step S1005. If a rightward direction key is sensed, in Step S1003, the control unit 110 moves the cursor rightwards as much as the rotation angle, in Step S1005. Preferably, the rotation angle is normalized and sensed, as has been described with reference to FIGS. 6A and 7A, and the cursor moves accordingly.

After highlighting a desired menu, in Steps S1003-S1005, the user can execute the menu by using a selection key or confirmation key. When the user makes an input via the selection key so as to select the highlighted menu, the control unit 110 senses the input, in Step S1009, and executes the selected menu, in Step S1011.

As apparent from the above description, the present invention provides a method for operating a portable terminal adapted to conduct an input function according as the bodies of the portable terminal rotate. Particularly, when the user selects a specific list or function, which has a wide range of selection between upper and lower limits, an easy and quick movement for that selection is made based on rotation of the bodies. In addition, when a menu needs fine adjustment, the menu can be intuitively adjusted based on rotation of the bodies. This guarantees convenient use of the portable terminal.

While exemplary embodiments of the present invention have been shown and described in this specification, it will be understood by those skilled in the art that various changes or modifications of the embodiments are possible without departing from the spirit and scope of the invention as defined by the appended claims.

What is claimed is:

1. An apparatus for operating a portable terminal, the apparatus comprising:
a planar first body;
a planar second body connected to the planar first body so as to rotate about an eccentric hinge axis extending through a lateral surface of the planar first body in a longitudinal direction of the planar first body;
a rotation-sensing unit for sensing a rotation of at least one of the planar first and second bodies; and
a control unit for controlling the portable terminal according to the rotation.

2. The apparatus as claimed in claim 1, wherein the control unit controls the portable terminal according to a key input signal together with the rotation.

3. The apparatus as claimed in claim 1, wherein the rotation-sensing unit senses at least one of a rotation angle and a rotation direction.

4. The apparatus as claimed in claim 3, wherein the rotation-sensing unit senses the rotation angle by measuring a displacement from an initial location to a later location when at least one of the planar first and second bodies rotates.

5. The apparatus as claimed in claim 3, wherein the rotation-sensing unit sense the rotation angle and normalizes the rotation angle.

6. The apparatus as claimed in claim 3, wherein the rotation-sensing unit linearly senses the rotation angle.

7. A method for operating a portable terminal having a planar first body and a planar second body connected to the planar first body so as to rotate about an eccentric hinge axis extending through a lateral surface of the planar first body in a longitudinal direction of the planar first body, the method comprising:
sensing a rotation of least one of the planar first and second bodies and an optional key input in a predetermined mode; and
controlling the portable terminal according to the key input and the rotation.

8. The method as claimed in claim 7, wherein the sensing step comprises sensing at least one of a rotation angle and a rotation direction.

9. The method as claimed in claim 8, wherein the sensing step comprises measuring a displacement from an initial location to a later location when at least one of the planar first and second bodies rotates.

10. The method as claimed in claim 8, wherein the sensing step comprises normalizing the rotation angle into a number in a predetermined range so as to correspond to a predetermined function of the portable terminal.

11. The method as claimed in claim 8, wherein the sensing step comprises sensing the rotation angle so that the rotation angle linearly corresponds to a predetermined function of the portable terminal.

12. A method for operating a portable terminal having a planar first body and a planar second body connected to the first body so as to rotate about an eccentric hinge axis extending through a lateral surface of the planar first body in a longitudinal direction of the planar first body, the method comprising:
sensing a rotation angle of the planar first and second bodies and a key input in a mode for watching a digital broadcast; and
adjusting a broadcasting channel according to the rotation angle and the key input.

13. The method as claimed in claim 12, wherein the rotation angle is normalized so as to correspond to a channel number of the digital broadcast.

14. The method as claimed in claim 12, wherein the adjusting step comprises increasing the broadcasting channel according to the rotation angle when the key input is from an upward direction key.

15. The method as claimed in claim 12, the adjusting step comprises decreasing the broadcasting channel according to the rotation angle when the key input is from a downward direction key.

16. The method as claimed in claim 12, wherein the adjusting step comprises resetting the broadcasting channel to an initial channel when the key input is from by a reset key.

17. A method for operating a portable terminal having a planar first body and a planar second body connected to the planar first body so as to rotate about an eccentric hinge axis extending through a lateral surface of the planar first body in a longitudinal direction of the planar first body, the method comprising:
sensing a rotation angle and a rotation direction of at least one of the planar first and second bodies in a preview screen mode of a camera function; and
adjusting a preview screen according to the rotation angle and the rotation direction.

18. The method as claimed in claim 17, wherein the rotation angle is brought into a linear proportion to a magnification of a lens of the camera function of the portable terminal.

19. The method as claimed in claim 17, wherein the adjusting step comprises zooming-in the preview screen according to the rotation angle when the rotation direction faces clockwise.

20. The method as claimed in claim 17, wherein the adjusting step comprises zooming out the preview screen according to the rotation angle when the rotation direction faces counterclockwise.

21. A method for operating a portable terminal having a planar first body and a planar second body connected to the planar first body so as to rotate about an eccentric hinge axis extending through a lateral surface of the planar first body in a longitudinal direction of the planar first body, the method comprising:
locating a cursor at a menu on a main menu screen so as to highlight the menu;
sensing a rotation angle of the planar first and second bodies and a direction key input when at least one of the planar first and second bodies rotates;
moving the cursor according to the rotation angle and the direction key input; and
highlighting a menu, the cursor having moved to the menu.

22. The method as claimed in claim 21, wherein the moving step comprises moving the cursor upwards according to the rotation angle when the direction key is an upward direction key.

23. The method as claimed in claim 21, wherein the moving step comprises moving the cursor downwards according to the rotation angle when the direction key is a downward direction key.

24. The method as claimed in claim 21, wherein the moving step comprises moving the cursor leftwards according to the rotation angle when the direction key is a leftward direction key.

25. The method as claimed in claim 21, wherein the moving step comprises moving the cursor rightwards according to the rotation angle when the direction key is a rightward direction key.
